(19) United States
(12) Patent Application Publication
(10) Pub. No.: US 2026/0182391 A1
(43) Pub. Date: Jun. 25, 2026

(54) METHOD OF MANUFACTURING INTERCONNECT SUBSTRATE

(71) Applicant: SHINKO ELECTRIC INDUSTRIES CO., LTD., Nagano (JP)

(72) Inventor: Kenta NAKAMURA, Nagano (JP)

(21) Appl. No.: 19/425,078

(22) Filed: Dec. 18, 2025

(30) Foreign Application Priority Data
Dec. 24, 2024 (JP) 2024-227352

(51) Int. Cl. H10W 70/02

(52) U.S. Cl. CPC H10W 70/027

(57) ABSTRACT

A method includes providing a structure including a first interconnect layer, an electronic component having an electrode, and an insulating layer covering both the first interconnect layer and an electrode side of the electronic component, forming a first via hole penetrating the insulating layer and exposing the first interconnect layer, performing desmearing after forming the first via hole, forming, after the desmearing, a second via hole smaller than the first via hole to penetrate the insulating layer and expose the electrode, performing anisotropic wet etching on the first interconnect layer exposed in the first via hole and the electrode exposed in the second via hole after forming the second via hole, and forming, by plating after the anisotropic wet etching, a second interconnect layer including an interconnect connected to the first interconnect layer via the first via hole and an interconnect connected to the electrode via the second via hole.

### CROSS-REFERENCE TO RELATED APPLICATIONS

The present application is based on and claims priority to Japanese Patent Application No. 2024-227352 filed on December 24, 2024, with the Japanese Patent Office, the entire contents of which are incorporated herein by reference.

### FIELD

The disclosures herein generally relate to methods of manufacturing an interconnect substrate.

### BACKGROUND

Interconnect substrates as known in the art may each include a cavity penetrating a first insulating layer, a semiconductor device accommodated in the cavity, a first interconnect layer formed on the first insulating layer, a second insulating layer laminated on the first insulating layer and covering the first interconnect layer and the semiconductor device, and a second interconnect layer formed on the second insulating layer.

In such an interconnect substrate, a part of the second interconnect layer is connected to the first interconnect layer via a first via hole penetrating the second insulating layer, and a part of the second interconnect layer is connected to the semiconductor device via a second via hole penetrating the second insulating layer. The opening area of the second via hole is smaller than the opening area of the first via hole (for example, see Patent Document 1).

In the manufacturing process of an interconnect substrate with via holes having different opening areas as described above, a process of simultaneously removing resin residues in the via holes having different opening areas is likely to cause delamination of an insulating layer from an interconnect layer around the via holes of small opening areas. The delamination may cause a short circuit between adjacent elements of the interconnect layer when forming an interconnect layer for filling the via holes of small opening areas.

### [Related Art Document]

### [Patent Document]

[Patent Document 1] Japanese Laid-open Patent Publication No. 2017-162848

### SUMMARY

According to an aspect of the embodiment, a method of manufacturing an interconnect substrate includes providing a structure including a first interconnect layer, an electronic component having an electrode, and an insulating layer covering both the first interconnect layer and an electrode side of the electronic component, forming a first via hole penetrating the insulating layer and exposing an upper surface of the first interconnect layer, performing desmearing after forming the first via hole, forming, after the desmearing, a second via hole having an opening area smaller than that of the first via hole so as to penetrate the insulating layer and expose an upper surface of the electrode, performing anisotropic wet etching on the first interconnect layer exposed in the first via hole and the electrode exposed in the second via hole after forming the second via hole, and forming, by plating after the anisotropic wet etching, a second interconnect layer including an interconnect connected to the first interconnect layer via the first via hole and an interconnect connected to the electrode via the second via hole.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a cross-sectional view illustrating an example of an interconnect substrate according to a present embodiment;

FIGS. 2A through 2C are drawings illustrating an example of a manufacturing process of the interconnect substrate according to the present embodiment; and

FIGS. 3A through 3C are drawings illustrating the example of the manufacturing process of the interconnect substrate according to the present embodiment.

### DESCRIPTION OF EMBODIMENTS

Embodiments of the invention will be described below with reference to the accompanying drawings. In these drawings, the same components are denoted by the same reference numerals, and duplicate descriptions may be omitted.

### [Structure of Interconnect Substrate]

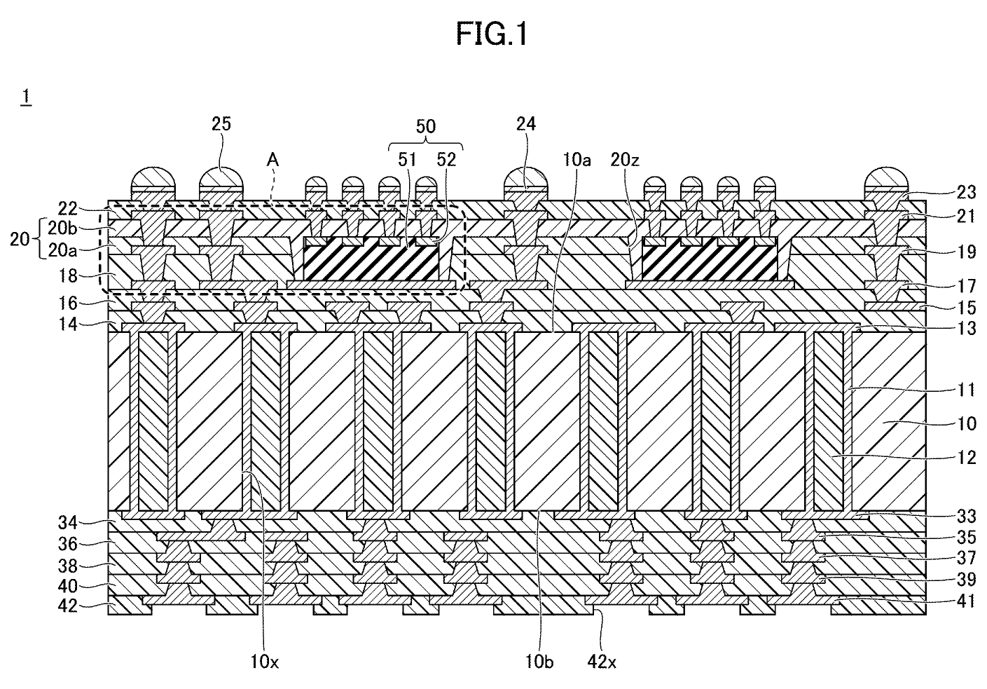

FIG. 1 is a cross-sectional view illustrating an example of an interconnect substrate according to a present embodiment. Referring to FIG. 1, an interconnect substrate 1 is configured such that interconnect layers and insulating layers are laminated on both surfaces of a core layer 10.

In the interconnect substrate 1, an interconnect layer 13, an insulating layer 14, an interconnect layer 15, an insulating layer 16, an interconnect layer 17, an insulating layer 18, an interconnect layer 19, an insulating layer 20, an interconnect layer 21, a solder resist layer 22, and an interconnect layer 23 are sequentially laminated on the upper surface 10a of a core layer 10. On the lower surface 10b of the core layer 10, an interconnect layer 33, an insulating layer 34, an interconnect layer 35, an insulating layer 36, an interconnect layer 37, an insulating layer 38, an interconnect layer 39, an insulating layer 40, an interconnect layer 41, and a solder resist layer 42 are sequentially laminated. The numbers of interconnect layers and insulating layers stacked on the upper surface 10a and the lower surface 10b of the core layer 10 are not limited to those of the example illustrated in FIG. 1.

In the present embodiment, for convenience, the solder resist layer 22 side of the interconnect substrate 1 is referred to as an upper side or a first side, and the solder resist layer 42 side is referred to as a lower side or a second side. The surface of a portion oriented in the same direction as the solder resist layer 22 side is referred to as a first surface or an upper surface, and the surface of the portion oriented in the same direction as the solder resist layer 42 side is referred to as a second surface or a lower surface. However, the interconnect substrate 1 may be positioned upside down when used, or may be arranged at any angle. The plan view refers to the view of an object as seen from the direction normal to the upper surface 10a of the core layer 10, and the plan shape refers to the shape of an object as seen from the direction normal to the upper surface 10a of the core layer 10.

The core layer 10 may be, for example, a glass epoxy substrate formed by impregnating a glass cloth with an insulating resin such as an epoxy-based resin. Alternatively, the core layer 10 may be a substrate formed by impregnating a woven fabric or a nonwoven fabric of fiber such as glass fiber, carbon fiber, or aramid fiber with an epoxy-based resin or the like. The thickness of the core layer 10 is, for example, in the range of approximately 60 to 1600 μm. The core layer 10 is provided with through holes 10x penetrating the core layer 10 in the thickness direction. The plan shape of each through hole 10x is, for example, circular.

The interconnect layer 13 is formed on the upper surface 10a of the core layer 10. The interconnect layer 23 is formed on the lower surface 10b of the core layer 10. The interconnect layer 13 and the interconnect layer 23 are electrically connected by through interconnects 11 formed in the through holes 10x. In the illustrated example, a resin body 12 fills the central inner space of each through interconnect 11. The resin body 12 is, for example, cylindrical. The through interconnects 11 may not have the resin bodies 12. In this case, the through holes 10x are each fully filled with the through interconnect 11.

Each of the interconnect layers 13 and 23 is patterned in a predetermined plan shape. The interconnect layers 13 and 23 and the through interconnects 11 may be made of, for example, copper (Cu) or the like. The thicknesses of the interconnect layers 13 and 23 are, for example, in the range of approximately 25 to 45 μm. The interconnect layer 13, the interconnect layer 23, and the through interconnects 11 may be seamlessly formed.

The insulating layer 14 is formed on the upper surface 10a of the core layer 10 and covers the interconnect layer 13. The material of the insulating layer 14 may be an insulating resin mainly composed of, for example, an epoxy-based resin or a polyimide-based resin. The thickness of the insulating layer 14 may be, for example, in the range of approximately 30 to 40 μm. The insulating layer 14 may contain a filler such as silica (SiO₂).

The interconnect layer 15 is formed on the first side of the insulating layer 14. The interconnect layer 15 includes via interconnects that fill via holes penetrating the insulating layer 14 and reaching the upper surface of the interconnect layer 13, and an interconnect pattern formed on the upper surface of the insulating layer 14. The interconnect pattern is electrically connected to the interconnect layer 13 via the via interconnects. The material of the interconnect layer 15 and the thickness of the interconnect pattern may be substantially the same as those of the interconnect layer 13, for example.

The insulating layer 16 is formed on the upper surface of the insulating layer 14 so as to cover the interconnect layer 15. The material and the thickness of the insulating layer 16 may be substantially the same as those of the insulating layer 14, for example. The insulating layer 16 may contain a filler such as silica (SiO₂).

The interconnect layer 17 is formed on the first side of the insulating layer 16. The interconnect layer 17 includes via interconnects that fill via holes penetrating the insulating layer 16 and reaching the upper surface of the interconnect layer 15, and an interconnect pattern formed on the upper surface of the insulating layer 16. The interconnect pattern is electrically connected to the interconnect layer 15 through the via interconnects. The material of the interconnect layer 17 and the thickness of the interconnect pattern may be substantially the same as those of the interconnect layer 13, for example.

The insulating layer 18 is formed on the upper surface of the insulating layer 16 so as to cover the interconnect layer 17. The material and the thickness of the insulating layer 18 may be substantially the same as those of the insulating layer 14, for example. The insulating layer 18 may contain a filler such as silica (SiO₂).

The interconnect layer 19 is formed on the first side of the insulating layer 18. The interconnect layer 19 includes via interconnects that fill via holes penetrating the insulating layer 18 and reaching the upper surface of the interconnect layer 17, and an interconnect pattern formed on the upper surface of the insulating layer 18. The interconnect pattern is electrically connected to the interconnect layer 17 through the via interconnects. The material of the interconnect layer 19 and the thickness of the interconnect pattern may be substantially the same as those of the interconnect layer 13, for example.

The insulating layer 20 is formed on the upper surface of the insulating layer 18 so as to cover the interconnect layer 19. The insulating layer 20 has a 2-layer structure in which an upper insulating layer 20b is laminated on a lower insulating layer 20a. The materials of the lower insulating layer 20a and the upper insulating layer 20b may be, for example, substantially the same as that of the insulating layer 14. The total thickness of the lower insulating layer 20a and the upper insulating layer 20b may be, for example, substantially the same as that of the insulating layer 14. The lower insulating layer 20a and the upper insulating layer 20b may contain a filler such as silica (SiO₂).

A cavity 20z, which penetrates the insulating layer 18 and the lower insulating layer 20a to reach the upper surface of the interconnect layer 17, is formed in the insulating layer 18 and the lower insulating layer 20a. An electronic component 50 is disposed in the cavity 20z. The electronic component 50 includes a core 51 and electrodes 52 formed on the electrode-forming surface of the core 51. The electronic component 50 is disposed face up on the upper surface of the interconnect layer 17 located in the cavity 20z with the electrodes 52 facing upward. The upper insulating layer 20b is formed on the lower insulating layer 20a and fills the cavity 20z to cover the electronic component 50. The surface of the core 51 covered with the upper insulating layer 20b is made of, for example, silicon nitride.

The electronic component 50 may be a passive component or an active component. The electronic component 50 may be, for example, an IPD (integrated passive device), a semiconductor chip, a capacitor, an inductor, a resistor, or the like. The plan shape of the cavity 20z is, for example, geometrically similar to the plan shape of the electronic component 50, and its size is larger than that of the electronic component 50. A plurality of electronic components 50 may be arranged in one cavity 20z. The number of cavities 20z is not limited to the illustrated example.

The interconnect layer 21 is formed on the first side of the insulating layer 20. The interconnect layer 21 includes via interconnects that fill via holes penetrating the insulating layer 20 and reaching the upper surface of the interconnect layer 19, and an interconnect pattern formed on the upper surface of the insulating layer 20. The interconnect pattern is electrically connected to the interconnect layer 19 through the via interconnects. The interconnect layer 21 includes via interconnects that fill via holes penetrating the insulating layer 20 and reaching the upper surfaces of the electrodes 52, and an interconnect pattern formed on the upper surface of the insulating layer 20. The interconnect pattern is electrically connected to the electrodes 52 through the via interconnects. The material of the interconnect layer 21 and the thickness of the interconnect pattern may be substantially the same as those of the interconnect layer 13, for example.

The solder resist layer 22 is a protective insulating layer located as the outermost layer on the first side of the interconnect substrate 1, and is formed on the upper surface of the insulating layer 20 so as to cover the interconnect layer 21. The solder resist layer 22 may be formed of, for example, photosensitive epoxy-based insulating resin or acrylic-based insulating resin. The thickness of the solder resist layer 22 is, for example, in the range of approximately 15 to 35 μm.

The interconnect layer 23 is formed on the first side of the solder resist layer 22. The interconnect layer 23 includes via interconnects that fill via holes penetrating the solder resist layer 22 and reaching the upper surface of the interconnect layer 21, and pads formed on the upper surface of the solder resist layer 22. The pads are electrically connected to the interconnect layer 21 through via interconnects. The material of the interconnect layer 23 and the thicknesses of the pads may be substantially the same as those of the interconnect layer 13, for example. The interconnect layer 23 may include an interconnect pattern in addition to the pads.

A metal layer 24 may be formed on the upper surface of the interconnect layer 23. Examples of the metal layer include an Au layer, a Ni/Au layer (a metal layer made by laminating a Ni layer and an Au layer in this order), a Ni/Pd/Au layer (a metal layer made by laminating a Ni layer, a Pd layer, and an Au layer in this order), and a Sn layer.

External connection terminals 25 such as solder balls may be formed on the upper surface of the metal layer 24. The external connection terminals 25 may be used for electrical connections with an electronic component such as a semiconductor chip, for example.

The insulating layer 34 is formed on the lower surface 10b of the core layer 10 and covers the interconnect layer 33. The material and thickness of the insulating layer 34 may be substantially the same as those of the insulating layer 14, for example. The insulating layer 34 may contain a filler such as silica (SiO₂).

The interconnect layer 35 is formed on the second side of the insulating layer 34. The interconnect layer 35 includes via interconnects that fill via holes penetrating the insulating layer 34 and reaching the lower surface of the interconnect layer 33, and an interconnect pattern formed on the lower surface of the insulating layer 34. The interconnect pattern is electrically connected to the interconnect layer 33 through the via interconnects. The material of the interconnect layer 35 and the thickness of the interconnect pattern may be substantially the same as those of the interconnect layer 13, for example.

The insulating layer 36 is formed on the lower surface of the insulating layer 34 and covers the interconnect layer 35. The material and the thickness of the insulating layer 36 may be substantially the same as those of the insulating layer 14, for example. The insulating layer 36 may contain a filler such as silica (SiO₂).

The interconnect layer 37 is formed on the second side of the insulating layer 36. The interconnect layer 37 includes via interconnects that fill via holes penetrating the insulating layer 36 and reaching the lower surface of the interconnect layer 35, and an interconnect pattern formed on the lower surface of the insulating layer 36. The interconnect pattern is electrically connected to the interconnect layer 35 through the via interconnects. The material of the interconnect layer 37 and the thickness of the interconnect pattern may be substantially the same as those of the interconnect layer 13, for example.

The insulating layer 38 is formed on the lower surface of the insulating layer 36 and covers the interconnect layer 37. The material and the thickness of the insulating layer 38 may be, for example, substantially the same as those of the insulating layer 14. The insulating layer 38 may contain a filler such as silica (SiO₂).

The interconnect layer 39 is formed on the second side of the insulating layer 38. The interconnect layer 39 includes via interconnects that fill via holes penetrating the insulating layer 38 and reaching the lower surface of the interconnect layer 37, and an interconnect pattern formed on the lower surface of the insulating layer 38. The interconnect pattern is electrically connected to the interconnect layer 37 through the via interconnects. The material of the interconnect layer 39 and the thickness of the interconnect pattern may be, for example, substantially the same as those of the interconnect layer 13.

The insulating layer 40 is formed on the lower surface of the insulating layer 38 and covers the interconnect layer 39. The material and the thickness of the insulating layer 40 may be, for example, substantially the same as those of the insulating layer 14. The insulating layer 40 may contain a filler such as silica (SiO₂).

The interconnect layer 41 is formed on the second side of the insulating layer 40. The interconnect layer 41 includes via interconnects that fill via holes penetrating the insulating layer 40 and reaching the lower surface of the interconnect layer 39, and an interconnect pattern formed on the lower surface of the insulating layer 40. The interconnect pattern is electrically connected to the interconnect layer 39 through via interconnects. The material of the interconnect layer 41 and the thickness of the interconnect pattern may be, for example, substantially the same as those of the interconnect layer 13.

The solder resist layer 42 is a protective insulating layer located as the outermost layer on the second side of the interconnect substrate 1, and is formed on the lower surface of the insulating layer 40 to cover the interconnect layer 41. The material and the thickness of the solder resist layer 42 may be, for example, substantially the same as those of the solder resist layer 22. The solder resist layer 42 has openings 42x, and portions of the lower surface of the interconnect layer 41 are exposed within the openings 42x. The plan shape of each of the openings 42x may be, for example, circular. The interconnect layer 41 exposed in the openings 42x may be used as pads for electrical connections to a mounting substrate such as a motherboard. If necessary, a metal layer of the kind previously described may be formed on the lower surface of the interconnect layer 41 exposed in the openings 42x, or an oxidation prevention treatment such as OSP treatment may be applied.

### [Method of Manufacturing Interconnect Substrate]

The interconnect substrate 1 may be manufactured by a build-up method.

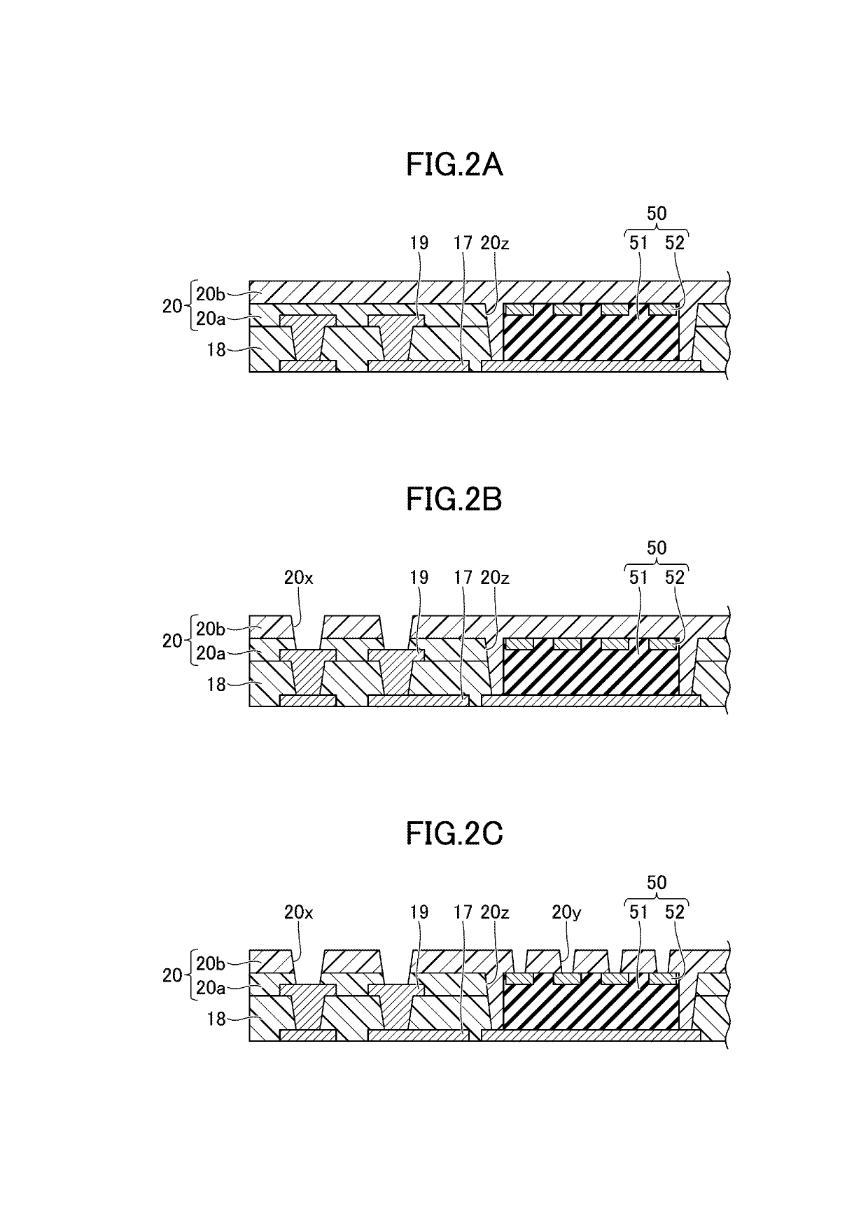

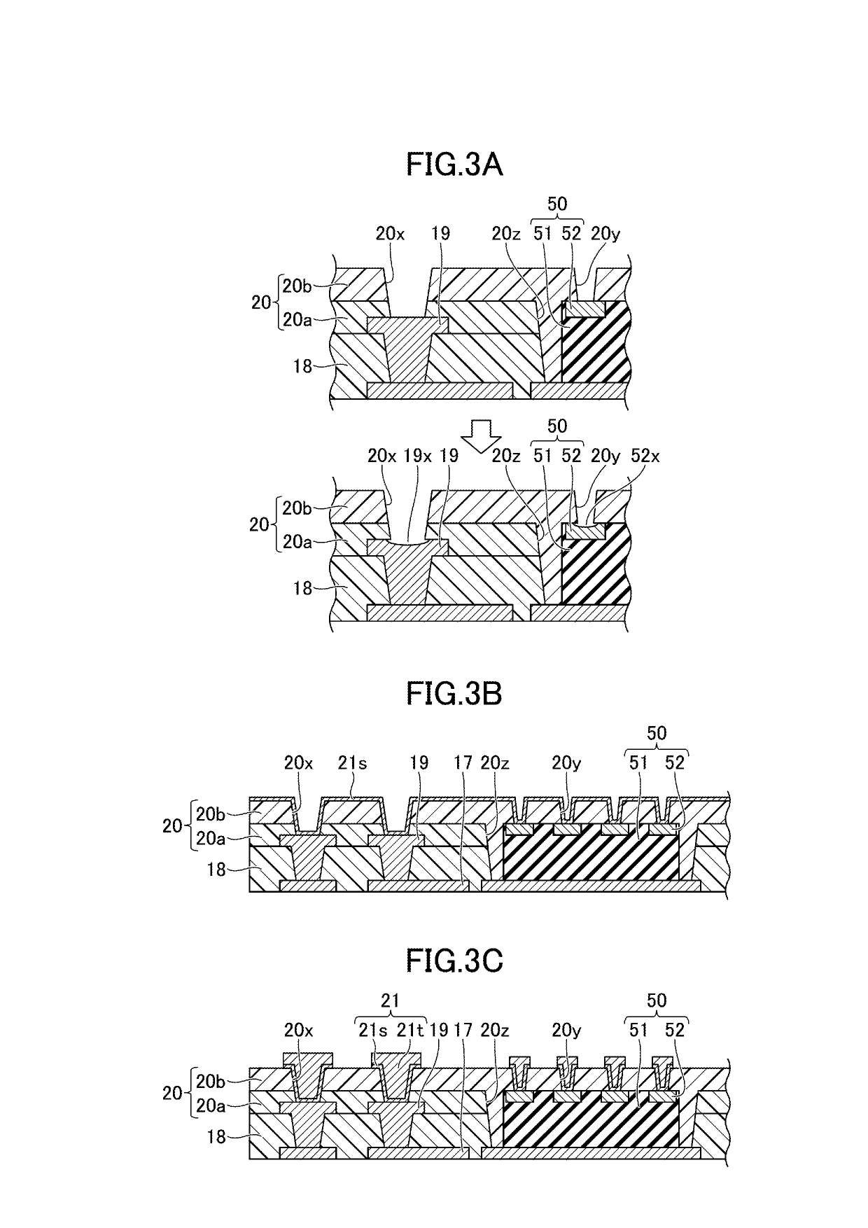

In the following, a part of a method of manufacturing the interconnect substrate 1 will be described. FIGS. 2A through 2C to FIGS. 3A through 3C are drawings illustrating an example of a manufacturing process of the interconnect substrate according to the present embodiment, and are cross-sectional views corresponding to a portion A in FIG. 1.

First, in the step illustrated in FIG. 2A, a structure is prepared that includes an interconnect layer 17, an insulating layer 18, an interconnect layer 19, an electronic component 50 having a core 51 and electrodes 52, and an insulating layer 20 covering the interconnect layer 19 and the electrode 52 side of the electronic component 50. The insulating layer 20 includes a lower insulating layer 20a and an upper insulating layer 20b.

To be more specific, first, an insulating layer 18 is formed so as to cover the interconnect layer 17. The insulating layer 18 may be formed, for example, by laminating and curing a semi-cured epoxy-based resin film or the like so as to cover the interconnect layer 17. Next, via holes penetrating the insulating layer 18 and exposing the upper surface of the interconnect layer 17 are formed in the insulating layer 18 by laser drilling or the like. Then, the via holes are filled by a plating method using copper or the like to form an interconnect layer 19 which is electrically connected to the interconnect layer 17 and extends from the inside of the via holes to the upper surface of the insulating layer 18.

A lower insulating layer 20a is formed on the insulating layer 18 so as to cover the interconnect layer 19. The lower insulating layer 20a may be formed, for example, in substantially the same manner as the insulating layer 18. A cavity 20z which penetrates the lower insulating layer 20a and the insulating layer 18 and exposes the upper surface of the interconnect layer 17 is formed by laser machining or the like, and an electronic component 50 is mounted face-up in the cavity 20z. An upper insulating layer 20b is formed on the lower insulating layer 20a so as to fill the cavity 20z and cover the electronic component 50. The upper insulating layer 20b may be formed, for example, in substantially the same manner as the insulating layer 18. The lower insulating layer 20a and the upper insulating layer 20b constitute an insulating layer 20, which serves as an interlayer insulating layer.

In the step illustrated in FIG. 2B, via holes 20x penetrating the insulating layer 20 and exposing the upper surface of the interconnect layer 19 are formed in the insulating layer 20. The via holes 20x may be formed, for example, by laser drilling using a carbon dioxide laser. The via holes 20x are, for example, each an inverted truncated conical hole with an opening area larger than the area of the bottom surface formed by the upper surface of the interconnect layer 19. Here, the term “opening area” refers to the area of the via hole 20x measured in the same plane as the upper surface of the insulating layer 20. The shape of the opening of the via hole 20x is, for example, circular in plan view. In this case, the opening diameter of the via hole 20x is, for example, from 40 μm to 60 μm. The term “opening diameter” refers to the diameter of the via hole 20x existing in the same plane as the upper surface of the insulating layer 20.

After the via holes 20x are formed, desmearing is performed to remove the resin residues of the insulating layer 20 adhering to the via holes 20x. In the desmearing, for example, for the interconnect layer 19 made of copper, an etching solution such as sodium permanganate or potassium permanganate may be used.

In the step illustrated in FIG. 2C, after the desmearing, via holes 20y are formed that penetrate the insulating layer 20 and expose the upper surfaces of the electrodes 52 of the electronic component 50. The opening area of each via hole 20y is smaller than the opening area of each via hole 20x. The via holes 20y may be formed, for example, by laser drilling using an ultraviolet laser. The ultraviolet laser may form a via hole having a smaller opening area than the carbon dioxide laser. The via holes 20y are, for example, each an inverted truncated conical hole with an opening area larger than the area of the bottom surface formed by the upper surface of an electrode 52. Here, the term “opening area” refers to the area of the via hole 20y measured in the same plane as the upper surface of the insulating layer 20. The shape of the opening of the via hole 20y is, for example, circular in plan view. In this case, the opening diameter of the via hole 20y is, for example, from 10 μm to 30 μm. The term “opening diameter” refers to the diameter of the via hole 20y existing in the same plane as the upper surface of the insulating layer 20.

In the step illustrated in FIG. 3A, the interconnect layer 19 exposed in the via holes 20x and the electrodes 52 exposed in the via holes 20y are subjected to anisotropic wet etching. In FIG. 3A, what is illustrated above the arrow is a view before the anisotropic wet etching, and is an enlarged view of a portion in FIG. 2C. What is illustrated below the arrow is a view after the anisotropic wet etching.

As illustrated below the arrow in FIG. 3A, the anisotropic wet etching process forms a recess 19x in the upper surface of the interconnect layer 19 and a recess 52x in the upper surface of the electrode 52. The recess 19x, which is recessed from the upper surface toward the lower surface of the interconnect layer 19, is continuous with the via hole 20x, and is formed so as to extend further outwards than the lower edge of the inner surface of the via hole 20x in plan view. The recess 52x, which is recessed from the upper surface toward the lower surface of the electrode 52, is continuous with the via hole 20y, and is formed so as to extend further outwards than the lower edge of the inner surface of the via hole 20y in plan view. That is, the peripheries of the recesses 19x and 52x overlap with the insulating layer 20 in plan view. The portions of the peripheries of the recesses 19x and 52x that overlap with the insulating layer 20 in plan view are referred to as “undercut”. The surface roughness Ra of the upper surface of the insulating layer 20, the inner wall surface of the via hole 20x, and the inner wall surface of the via hole 20y is in the range of approximately 10 to 350 nm as a result of the anisotropic wet etching.

The recesses 19x and 52x each have, for example, a bowl shape. That is, the inner surfaces of the recess 19x and 52x each have an arcuate profile, and are each curved to lower gradually from the periphery toward the center. In plan view, the center of the recess 19x substantially coincides with the center of the via hole 20x. In plan view, the center of the recess 52x substantially coincides with the center of the via hole 20y.

The anisotropic wet etching uses a weak alkaline etchant capable of etching the interconnect layer 19 and the electrodes 52. For example, for the interconnect layer 19 and the electrodes 52 made of copper, an etchant such as a mixture of copper ammine complex salt and ammonia may be used. The use of the anisotropic etchant effectively reduces the sizes of undercuts in the recesses 19x and 52x.

It may be noted that, between the step of forming the via holes 20y and the step of performing the anisotropic wet etching, an additional step is preferably provided to perform plasma treatment on the interconnect layer 19 exposed in the via holes 20x and the electrodes 52 exposed in the via holes 20y. Such a plasma treatment enhances the hydrophilicity, thereby effectively spreading the anisotropic wet etching solution uniformly in the via holes 20y. For example, a fluorine-based gas such as carbon tetrafluoride (CF₄) gas may be used for the plasma treatment. Alternatively, a mixed gas of carbon tetrafluoride (CF₄) and oxygen (O₂) may be used.

In the steps illustrated in FIGS. 3B and 3C, after the anisotropic wet etching, an interconnect layer 21 including interconnects connected to the interconnect layer 19 via the via holes 20x and interconnects connected to the electrodes 52 via the via holes 20y is formed by plating.

First, as illustrated in FIG. 3B, electroless plating forms a seed layer 21s that is connected to the interconnect layer 19 via the via holes 20x and connected to the electrodes 52 via the via holes 20y. The seed layer 21s is formed to continuously cover the upper surface of the insulating layer 20, the inner wall surfaces of the via holes 20x, the upper surfaces of the interconnect layer 19 exposed in the via holes 20x, the inner wall surfaces of the via holes 20y, and the upper surfaces of the electrodes 52 exposed in the via holes 20y. The material of the seed layer 21s may be, for example, copper. Although the recesses 19x and 52x are not illustrated in FIG. 3B, the seed layer 21s also continuously covers the inner surfaces of the recesses 19x and 52x.

Next, as illustrated in FIG. 3C, a plating layer 21t is formed on the seed layer 21s by an electrolytic plating method. Specifically, a plating resist pattern having openings matching the shapes of the interconnects constituting the interconnect layer 21 is formed on the seed layer 21s illustrated in FIG. 3B. The plating layer 21t is then deposited on the seed layer 21s exposed in the openings of the plating resist pattern by an electrolytic plating method of copper or the like using the seed layer 21s as a current supply path. After removing the plating resist pattern, etching is performed using the plating layer 21t as a mask to remove the seed layer 21s exposed outside the plating layer 21t. This arrangement effectively forms the interconnect layer 21, which is composed of the seed layer 21s and the plating layer 21t laminated thereon. Since the interconnect layer 21 is also formed in the recesses 19x and 52x, the anchor effect effectively improves the adhesion between the interconnect layer 21 and the insulating layer 20.

It is preferable to include a step of performing ultrasonic cleaning between the step of performing the anisotropic wet etching and the step of forming the seed layer 21s of the interconnect layer 21. Performing the ultrasonic cleaning effectively removes fillers and the like remaining in the via holes, which were not removed by the anisotropic wet etching. Furthermore, it is preferable to include a step of performing a cleaner treatment between the step of performing the ultrasonic cleaning and the step of forming the seed layer 21s of the interconnect layer 21. Performing the cleaner treatment effectively improves the wettability of the inner walls of the via holes from which the fillers have been removed.

In conventional methods of manufacturing an interconnect substrate, the desmearing treatment is performed after the via holes 20x and 20y are formed. In this case, the desmearing treatment is performed under the condition aligned for the via holes 20x having large opening areas, so the via holes 20y having small opening areas are subjected to excessive desmearing.

As a result, the via holes 20y having small opening areas exhibit undercuts due to excessive desmearing, which makes it likely for delamination to occur at the interface between the electrodes 52 and the insulating layer 20. For example, when the shape of the opening of each via hole 20y is circular in plan view and the opening diameter is in the range of approximately 15 to 25 μm, the electrodes 52 are etched approximately 2.5 μm to 3.5 μm in the depth direction by the desmearing, and undercuts are formed to extend approximately 7 μm to 8.5 μm in the horizontal directions.

If the electroless plating is performed in the presence of delamination caused by the undercuts, the plated layer grows along the delaminated portion, potentially causing a short circuit between adjacent electrodes 52. In particular, if a soft etching treatment at the time of the electroless plating is performed in the presence of delamination, the undercuts grow far enough to reach the outer edges of the electrodes 52, causing delamination also at the interface between the core 51 and the insulating layer 20. Performing the electroless plating under such a condition causes the plated layer to grow along the delaminated portion, thereby increasing the likelihood that the adjacent electrodes 52 are short-circuited.

In contrast, the manufacturing method of the interconnect substrate 1 is configured such that, after the via holes 20x having large opening areas are formed, only the via holes 20x are subjected to desmearing before the via holes 20y having small opening areas are formed. With this arrangement, resin residues are effectively removed from the via holes 20x while avoiding the occurrence of undercuts in the via holes 20y resulting from excessive desmearing.

However, resin residues still need to be removed from the via holes 20y. The manufacturing method of the interconnect substrate 1 is thus configured such that the via holes 20y are subjected to the anisotropic wet etching instead of desmearing. This arrangement effectively removes resin residues on the electrodes 52 without causing large undercuts as in the case of isotropic wet etching. For example, when the shape of the opening of each via hole 20y is circular in plan view and the opening diameter is in the range of approximately 15 to 25 μm, the electrodes 52 are etched approximately 1.5 to 3.0 μm in the depth direction by the anisotropic wet etching, and undercuts are formed to extend approximately 0 to 1.5 μm in the horizontal directions.

As described above, the manufacturing method of the interconnect substrate 1 is free of a process that creates excessive undercuts in the via holes 20y, thereby reducing the likelihood of occurrence of delamination at the interface between the core 51 and the insulating layer 20 and at the interface between the electrodes 52 and the insulating layer 20. As a result, short-circuiting between adjacent electrodes 52 by the plating process is effectively suppressed. In particular, this method is effective for improving reliability and yield when the pitch between the electrodes 52 is narrowed.

Although the via holes 20x are also subjected to the anisotropic wet etching, excessive undercuts as in the isotropic wet etching do not occur, so that delamination is unlikely to occur at the interface between the interconnect layer 19 and the insulating layer 20.

According to at least one embodiment, delamination of an insulating layer from an interconnect layer is effectively reduced in a manufacturing process of an interconnect substrate with via holes having different opening areas.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. A method of manufacturing an interconnect substrate, comprising:
providing a structure including a first interconnect layer, an electronic component having an electrode, and an insulating layer covering both the first interconnect layer and an electrode side of the electronic component;
forming a first via hole penetrating the insulating layer and exposing an upper surface of the first interconnect layer;
performing desmearing after forming the first via hole;
forming, after the desmearing, a second via hole having an opening area smaller than that of the first via hole so as to penetrate the insulating layer and expose an upper surface of the electrode;
performing anisotropic wet etching on the first interconnect layer exposed in the first via hole and the electrode exposed in the second via hole after forming the second via hole; and
forming, by plating after the anisotropic wet etching, a second interconnect layer including an interconnect connected to the first interconnect layer via the first via hole and an interconnect connected to the electrode via the second via hole.

2. The method according to claim 1, further comprising performing a plasma treatment on the first interconnect layer exposed in the first via hole and the electrode exposed in the second via hole, between the forming of the second via hole and the performing of the wet etching.

3. The method according to claim 1, further comprising performing ultrasonic cleaning between the performing of the wet etching and the forming of the second interconnect layer.

4. The method according to claim 3, further comprising performing a cleaner treatment between the performing of the ultrasonic cleaning and the forming of the second interconnect layer.

5. The method according to claim 1, wherein the performing of the wet etching involves forming a first recess continuous with the first via hole in the first interconnect layer and a second recess continuous with the second via hole in the electrode,
wherein a periphery of the first recess and a periphery of the second recess overlap with the insulating layer in plan view.

6. The method according to claim 1, wherein the first via hole is formed by a carbon dioxide laser, and the second via hole is formed by an ultraviolet laser.

7. The method according to claim 1, wherein the forming of the second interconnect layer includes:
forming a seed layer connected to the first interconnect layer via the first via hole and connected to the electrode via the second via hole by electroless plating; and
forming a plating layer on the seed layer by electrolytic plating.
